(19) United States
(12) Patent Application Publication
(10) Pub. No.: US 2024/0411529 A1
(43) Pub. Date: Dec. 12, 2024

(54) DATA MODELING METHOD, APPARATUS AND DEVICE, AND STORAGE MEDIUM

(71) Applicant: Alibaba Innovation Private Limited, Singapore (SG)

(72) Inventors: Liang ZHAO, Zhejiang (CN); KuoLing HUANG, Pleasanton, CA (US); Wotao YIN, San Diego, CA (US)

(21) Appl. No.: 18/810,147

(22) Filed: Aug. 20, 2024

Related U.S. Application Data
(63) Continuation of application No. PCT/CN2023/075175, filed on Feb. 9, 2023.

(30) Foreign Application Priority Data
Feb. 25, 2022 (CN) 202210179833.3

(51) Int. Cl. G06F 8/35; G06F 8/41

(52) U.S. Cl. CPC G06F 8/35; G06F 8/447

(57) ABSTRACT

The present disclosure provides a data modeling method, apparatus, and a storage medium. The method includes: acquiring a model file and a data file, the model file including code for modeling a to-be-solved problem corresponding to a target application system, the code including a plurality of parameters, and the data file including parameter values corresponding to part of the parameters; in response to a running operation triggered for a target segment of the code in the model file and a determination that the target segment of the code including unassigned parameters, displaying prompt information corresponding to the unassigned parameters for prompting input of parameter values corresponding to the unassigned parameters; and generating a model instance corresponding to the target segment of the code according to the parameter values corresponding to the unassigned parameters inputted and parameter values corresponding to assigned parameters in the target segment of the code. Based on the novel model file running mode provided in some embodiments of the present disclosure, model debugging is more flexible, so that a better model can be formed.

### CROSS-REFERENCE TO RELATED APPLICATIONS

The disclosure claims the benefits of priority to PCT Application No. PCT/CN2023/075175, filed on Feb. 9, 2023, which claims the benefits of priority to Chinese Application No. 202210179833.3, filed on Feb. 25, 2022, both of which are incorporated herein by reference in their entireties.

### TECHNICAL FIELD

The present disclosure relates to the technical field of data processing, and specifically relates to a data modeling method, apparatus and device, and a storage medium.

### BACKGROUND

In many application scenarios, there are optimization problems that need to be solved, so mathematical modeling and solving of optimization problems has become a widely adopted solution idea. In a current process of using modeling tool software, users often need to prepare complete model files and data files, then call a certain modeling language to parse the model files, and load the corresponding data files to complete the modeling of a model instance, and finally use the solver to solve the model instance obtained by modeling. This mode has many inconveniences and is less flexible in the stage of model development and debugging.

### SUMMARY

The disclosed embodiments of the present disclosure provides a data modeling method, apparatus and device, and a storage medium, aiming to improve the modeling flexibility.

Some embodiments of the present disclosure provide a data modeling method, including: acquiring a model file and a data file, the model file including code for modeling a to-be-solved problem corresponding to a target application system, the code including a plurality of parameters, and the data file at least including parameter values corresponding to part of the parameters; in response to a running operation triggered for a target segment of the code in the model file and a determination that the target segment of the code including unassigned parameters, displaying prompt information corresponding to the unassigned parameters for prompting input of parameter values corresponding to the unassigned parameters; and generating a model instance corresponding to the target segment of the code according to the parameter values corresponding to the unassigned parameters inputted and parameter values corresponding to assigned parameters in the target segment of the code.

Some embodiments of the present disclosure provide a data modeling apparatus, including: a memory; and one or more processors communicatively coupled with the memory, the memory storing a set of instructions that are executable by one or more processors of the data modeling apparatus to cause the data modeling apparatus to perform operations, including: acquiring a model file and a data file, the model file including code for modeling a to-be-solved problem corresponding to a target application system, the code including a plurality of parameters, and the data file at least including parameter values corresponding to part of the parameters; in response to a running operation triggered for a target segment of the code in the model file and a determination that the target segment of the code including unassigned parameters, displaying prompt information corresponding to the unassigned parameters for prompting input of parameter values corresponding to the unassigned parameters; and generating a model instance corresponding to the target segment of the code according to the parameter values corresponding to the unassigned parameters inputted and parameter values corresponding to assigned parameters in the target segment of the code.

Some embodiments of the present disclosure provide non-transitory computer-readable storage medium, storing a set of instructions that are executable by one or more processors of a device to cause the device to perform operations for data modeling, the operations including: acquiring a model file and a data file, the model file including code for modeling a to-be-solved problem corresponding to a target application system, the code including a plurality of parameters, and the data file at least including parameter values corresponding to part of the parameters; in response to a running operation triggered for a target segment of the code in the model file and a determination that the target segment of the code including unassigned parameters, displaying prompt information corresponding to the unassigned parameters for prompting input of parameter values corresponding to the unassigned parameters; and generating a model instance corresponding to the target segment of the code according to the parameter values corresponding to the unassigned parameters inputted and parameter values corresponding to assigned parameters in the target segment of the code.

### DESCRIPTION OF THE DRAWINGS

Embodiments and various aspects of the present disclosure are illustrated in the following detailed description and the accompanying figures. Various features shown in the figures are not drawn to scale.

FIG. 1 is a schematic diagram of an exemplary modeling framework according to some embodiments of the present disclosure.

FIG. 2 is a flowchart of an exemplary data modeling method according to some embodiments of the present disclosure.

FIG. 3 is a schematic diagram of interface interaction of an exemplary modeling tool, according to some embodiments of the present disclosure.

FIG. 4 is a schematic diagram of interface interaction of an exemplary process of scanning unassigned parameters, according to some embodiments of the present disclosure.

FIG. 5 is a flowchart of another exemplary data modeling method according to some embodiments of the present disclosure.

FIG. 6 is a flowchart of another exemplary data modeling method of an electric power system, according to some embodiments of the present disclosure.

FIG. 7 is a schematic structural diagram of an exemplary data modeling apparatus according to some embodiments of the present disclosure.

FIG. 8 is a schematic structural diagram of an exemplary electronic device according to some embodiments of the present disclosure.

### DETAILED DESCRIPTION

Reference can now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the disclosure as recited in the appended claims. Particular aspects of present disclosure are described in greater detail below. The terms and definitions provided herein control, if in conflict with terms and/or definitions incorporated by reference.

According to some embodiments of the present disclosure, the model file may include the code for modeling the to-be-solved problem corresponding to the target application system, and the code can be mainly used for defining various functions, equations, inequations, variables and parameters corresponding to the to-be-solved problem. The data file may include related data required to be used in the model instance modeling process, and mainly includes parameter values of various parameters.

According to some embodiments of the present disclosure, when a developer develops the model file, the developer may not be required to set parameter values of all parameters in the model file. For example, corresponding parameter values or corresponding reading paths of the parameter values in a data file are directly given in the model file, but the developer is not required to perform assignment operation on the parameter values of some parameters. In addition, different from traditional modeling tool software that only allows to execute a complete model file in one modeling process, some embodiments of the present disclosure allow the user (which can be the developer or a debugger) to select part of the code in the model file to run. Based on this, when the user triggers the running operation for the target segment of the code in the model file, whether the target segment of the code includes unassigned parameters or not is firstly determined, and if it is found that the target segment of the code includes unassigned parameters after traversing is completed, the prompt information corresponding to the unassigned parameters is displayed for prompting the input of the corresponding parameter values. After the parameter values corresponding to the unassigned parameters inputted by the user based on the prompt information is received, the target segment of the code is run again, so that the model instance corresponding to the target segment of the code is generated according to the parameter values corresponding to the unassigned parameters inputted by the user and parameter values corresponding to assigned parameters in the target segment of the code.

In the modeling solution according to some embodiments of the present disclosure, the configuration modeling tool software may support the setting of unassigned parameters and a certain specific running mode. In this running mode, firstly, the unassigned parameters in the running code segment are traversed and determined, then prompt information is outputted to enable the user to input currently needed parameter values according to needs, and then the code segment runs to complete corresponding model instance modeling. This running mode is convenient for the user to debug the model file according to needs, so that the modeling process is high in flexibility.

In some embodiments of the present disclosure, a data modeling method provided by some embodiments of the present disclosure can be executed by an electronic device. The electronic device can be a server or a user terminal. The server can be a physical server or a virtual server (virtual machine) deployed in the cloud.

In some embodiments of the present disclosure, Integrated Development Environment (IDE for short) can be implemented. The IDE is an application program used for providing a program development environment and generally includes a code editor, a compiler, a debugger, a graphical user interface and other tools. The IDE is a software development service set integrating a code writing function, an analysis function, a compiling function, a debugging function and the like.

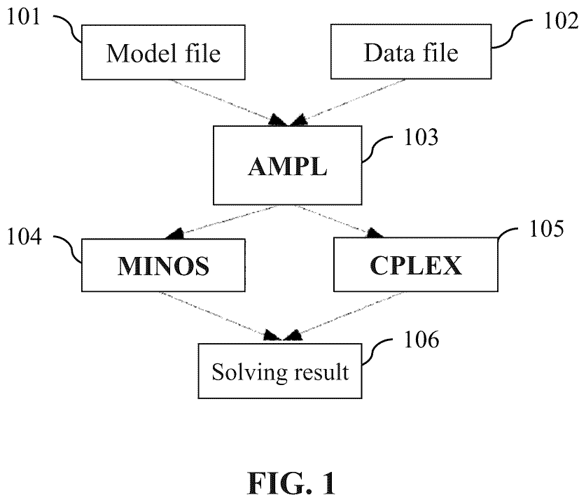

FIG. 1 is a schematic diagram of an exemplary modeling framework according to some embodiments of the present disclosure. Taking the modeling language tool AMPL as an example, a universal modeling framework in FIG. 1 can adopt this tool. As shown in FIG. 1, AMPL 103 reads a model file 101 and the data file 102 to generate a model instance, and then calls the solver capable of solving various mathematical programming problems (e.g., two solvers including MINOS 104 and CPLEX 105 are shown in FIG. 1) for solving to obtain a solution of a decision variable in the model instance to generate a solving result 106.

Herein, model file 101 can be realized by adopting a certain modeling language to compile a script program of a certain mathematical model defined by a user, for example. The mathematical model involved in some embodiments of the present disclosure may be modeled for some linear and nonlinear mathematical programming problems; and correspondingly, code in model file 101 is used for describing the mathematical models, such as an objective function, an equation or inequation constraint, a decision variable and various parameters. Moreover, data file 102 may include data required by modeling and generates store parameter values of various parameters defined in the model. A model instance can be a specific model modeled by combining data values loaded from a data source such as data file 102 based on the model definition described in model file 101. In summary, different data sources are different, and different model instances may be established for the same defined mathematical model.

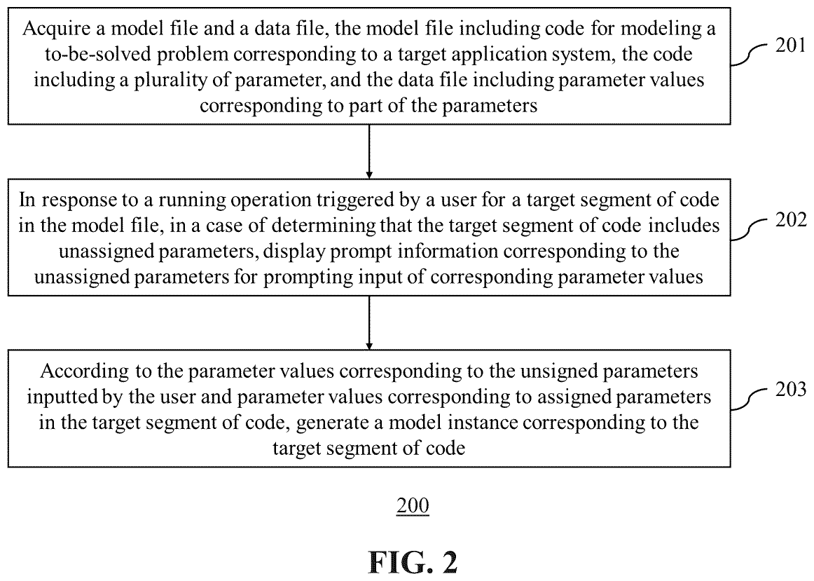

FIG. 2 is a flowchart of an exemplary data modeling method 200 according to some embodiments of the present disclosure. As shown in FIG. 2, method 200 includes the following steps 201 to 203, which can be implemented by a data modeling apparatus. The data modeling apparatus, which is described below, may include processing resources, storage resources, and communication interfaces.

In step 201, the data modeling apparatus can acquire a model file and a data file. The model file may include code for modeling a to-be-solved problem corresponding to a target application system. The code may include a plurality of parameters. The data file may at least include parameter values corresponding to part of the parameters. That is, the parameter values of at least some of the parameters are given and included in the data file.

In step 202, the data modeling apparatus can display prompt information corresponding to the unassigned parameters for prompting input of corresponding parameter values in response to a running operation triggered by a user for a target segment of the code in the model file and a determination that the target segment of the code including unassigned parameters.

In step 203, the data modeling apparatus can generate a model instance corresponding to the target segment of the code according to the parameter values corresponding to the unassigned parameters inputted by the user and parameter values corresponding to assigned parameters in the target segment of the code.

The target application system may be any application system with an optimization problem solving requirement, such as an electric power system. The problem to be solved can be an optimization problem for the electric power system, for example. The user may define a corresponding mathematical model based on the problem to be solved in the target application system. From the composition angle, generally, the mathematical model may include an objective function and a plurality of constraint conditions. The constraint conditions can be expressed in the form of an equation or an inequation. A plurality of decision variables and a plurality of parameters can be defined in the objective function and the constraint condition, while the decision variables are unknown variables to be solved. The parameters may generally include coefficients corresponding to the decision variables and some constant terms.

After the user defines the mathematical model, the program code script may be compiled by the modeling language provided by certain modeling tool software to form the model file. Mathematical symbols, operators and the like will be provided in the modeling language for the user to use, and the user needs to follow the grammar required by the modeling language when compiling the model file so that the model file can be smoothly executed.

Besides compiling the model file, a data file needs to be generated. As described above, the mathematical model defined by the user includes a plurality of parameters, parameter values corresponding to some parameters may be directly given in the model file compiled by the user, parameter values corresponding to some parameters may be loaded from the data file, and these parameter values often reflect the actual state information of the target application system, so that the data file needs to be generated by collecting the related actual state data of the target application system.

It is to be noted that in order to provide greater flexibility for the modeling process, different from a traditional modeling process in which the user must give parameter values corresponding to all parameters when compiling the model file, the user, in some embodiments of the present disclosure, does not need to assign the parameter values of some parameters. Therefore, in some embodiments of the present disclosure, the parameters in the model file may be divided into two types: assigned parameters and unassigned parameters.

It is to be noted that the assigned parameters in some embodiments of the present disclosure are not limited to parameters having parameter values that are directly given by the user, but also include parameters for which corresponding parameter value reading paths are given in the data file. The unassigned parameters refer to parameters having parameter values that are default or having default state that is represented by a set character.

Adaptive Modeling Language (AML) is an object-oriented full-automatic engineering design framework development tool for a complex system. A complex optimization model may be converted into an abstract algebraic expression form to be inputted in a script program, and each optimization solver may be connected. Common modeling language tools may include AMPL (A Mathematical Programming Language), GAMS (The General engineering Modeling System), FICO Xpress, AIMMS and the like. Common solvers include MindOpt, Gurobi, CPLEX and the like. For example, for a parameter x, a situation of directly giving the parameter value is as follows: x=10, while a situation that the reading path is given may be x={read “users/mdoAML/example/zpl/matching_set1.zpl”}, and the content in curly braces represents the reading path for reading the parameter value of the parameter x in the data file. A situation of an unassigned parameter may be as follows: x=&, wherein “&” represents a preset placeholder. That is, when the setting position of the parameter value of a certain parameter is occupied by a preset character, the parameter may be considered as an unassigned parameter, and the preset character is a predefined character representing the unassigned state of the parameter. In some embodiments, the parameter value of the parameter may also be set to be in a default state. That is, the parameter value setting position can be blank, so that the parameter is represented as an unassigned parameter.

As described above, the model file may include various variables to be solved in addition to parameters, and the variables are also in a state without corresponding values. Because different keywords are provided for definition of variables and parameters in the modeling language, which variables are parameters may be distinguished based on the keywords. For example, the keyword var is in front of the variables, and the keyword param is in front of the parameters.

In some embodiments, the user may decide which parameters are used as unassigned parameters, and which parameters give corresponding parameter values or parameter value reading paths. However, the final purpose of supporting the user to set the unassigned parameters is to facilitate debugging of a model by the user, so more flexibility and convenience are provided for establishing a proper mathematical model. Therefore, if the user sets most or even all parameters as unassigned parameters, or sets some parameters which are not necessarily set as unassigned parameters, unnecessary setting is generated. According to an execution process of the target segment of the code in the model file selected by the user under the “advanced running mode” described below, when there are unassigned parameters in the code execution process, the user needs to input the assignment of the unassigned parameters in real time based on the current requirement, and thus the purpose that different users or the same user may flexibly set the parameter values of the unassigned parameters as required when debugging a section of the code at different moments is achieved. Therefore, based on pre-analysis or expert suggestions, the user may be prompted to consider which types of parameters are set as unassigned parameters when modeling is carried out on a certain problem to be solved in the target application system. That is, these unassigned parameters are often parameters with special meanings, such as dates of data files, coefficients of certain variables in the model and other parts to be debugged and analyzed by users.

The date of the data file can be determined based on the following: in the model debugging process, it may be established corresponding model instances based on data files collected in different dates, or it may be determined whether the model needs to be modified or not based on the generated solving result of each model instance. In view of this, the parameter, namely the date of the data file, may be set as an unassigned parameter, so that the user can input the data files corresponding to different dates according to needs during debugging.

For the coefficient of a certain variable, in the model debugging process, the user may constantly update the value of the coefficient, so that the effect of the solution of different model instances finally formed when different values are taken can be observed.

The development of the model file may be completed by a certain user independently or cooperatively by a plurality of users. After the model file is preliminarily developed, model debugging can be needed. The debugging purpose is to check whether the designed mathematical model is reasonable or not, whether the compiled model file has errors or not and the like. In a traditional modeling tool, only the user is supported to debug the whole model file, namely, the whole model file needs to be executed in each debugging process. However, in the solution provided by some embodiments of the present disclosure, the user is supported to select part of the code in the model file to execute. For example, the involved mathematical model may include a plurality of constraint conditions, if the user wants to check whether a solution conforming to an expected variable can be obtained or not after removing part of the constraint conditions, the user may then select the remaining code of the code corresponding to the part of constraint conditions in the model file to operate. The code selected by the user to be executed is called the target segment of the code.

In order to be compatible with a running mode provided in a traditional modeling tool, in some embodiments of the present disclosure, the modeling tool supports the traditional running mode (which is distinguished as a conventional running mode), and a new running mode is also provided and is called an advanced running mode.

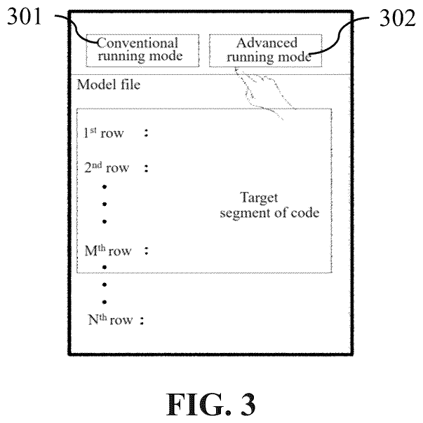

FIG. 3 is a schematic diagram of interface interaction of an exemplary modeling tool, according to some embodiments of the present disclosure. As shown in FIG. 3, in some embodiments, the user may firstly open the model file in an IDE of the modeling tool. In this interface, two running mode buttons shown in FIG. 3 may be provided: a “conventional running mode” button 301 and an “advanced running mode” button 302. It is assumed that the model file includes a plurality of rows of the code with the row numbers of 1-N shown in the figure, when the user selects 1-M rows of the code as the target section code and clicks the advanced running mode, the running of the target section code in the advanced running mode is executed, N>M>1.

The conventional running mode refers to a mode of running all code in the whole model file, and in this mode, all parameters in the model file are required to be assigned parameters. Conversely, in the advanced running mode, all or part of the code of the model file may be selected to run, and all or part of parameters in the model file being operated can be unassigned parameters.

In summary, when the target segment of the code is run in the advanced running mode, two running processes need to be executed: in the first running process, the main purpose is to analyze whether the target segment of the code include the unassigned parameters or not so as to prompt the user to assign the unassigned parameters after the first execution is finished; and the second execution process is a process of truly running the target segment of the code to establish the model instance corresponding to the target segment of the code based on the parameter values of the parameters contained in the target segment of the code.

As described above, the parameters included in the target segment of the code may be identified based on the setting keywords adopted during parameter definition.

Furthermore, the unassigned parameters can be determined according to whether the parameter values or parameter value reading paths are directly given at the setting positions of the parameter values, whether set placeholder characters representing that no parameter value is assigned are filled in or not, or whether the parameter value positions are in a default state or not. If it is determined that the target segment of the code includes unassigned parameters, prompt information may be displayed to prompt the user to input the parameter values corresponding to the unassigned parameters.

As described above, in step 202, based on the running operation (corresponding to the running operation of the advanced running mode) triggered by the user for the target segment of the code in the model file, whether the target segment of the code includes unassigned parameters or not is determined in the process of executing the target segment of the code for the first time. In some embodiments, the process of displaying prompt information corresponding to the unassigned parameters may specifically include the following sub-steps:

in the process of executing the target segment of the code for the first time, determining whether any row of the code includes unassigned parameters row by row;

in a case of determining that unassigned parameters are included, marking the unassigned parameters with a set character;

in a case that the target segment of the code is completely executed, acquiring all unassigned parameters in the target segment of the code according to the mark; and

displaying prompt information corresponding to all the unassigned parameters.

The set character is a placeholder character which is referred to in the above and represents that no parameter value is assigned. The user may mark the placeholders at parameter value setting positions of some unassigned parameters in the model file However, the parameter value setting positions corresponding to some unassigned parameters are in the default state (empty). In order to uniformly mark all unassigned parameters in the target segment of the code in the first execution process, the identified unassigned parameters can be uniformly marked with the set character, and the set character is marked at the parameter value setting position.

Besides, in some embodiments, displaying the prompt information corresponding to the unassigned parameters refers to uniformly prompting input of the parameter values of all the scanned unassigned parameters after completely traversing the target segment of the code.

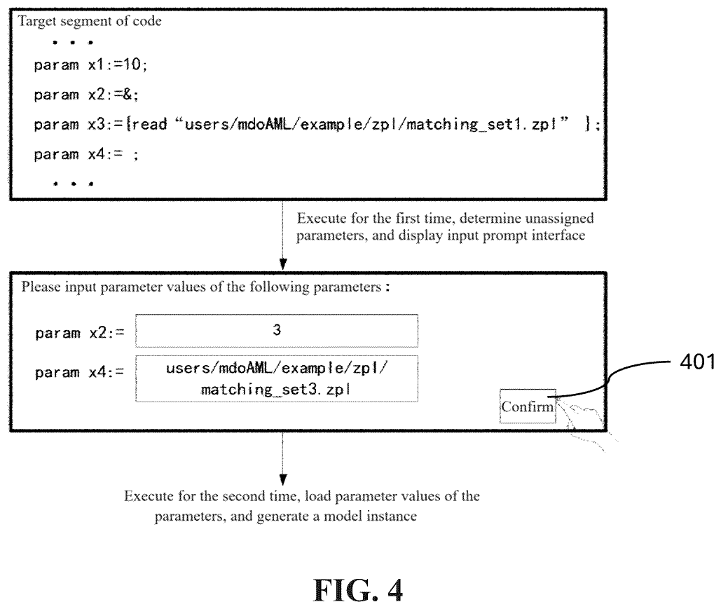

FIG. 4 is a schematic diagram of interface interaction of an exemplary process of scanning unassigned parameters, according to some embodiments of the present disclosure. As shown in FIG. 4, it is assumed that the selected target segment of the code in the template file may include the following four rows of code:

param x1:=10;

param x2:=&;

param x3:={read “users/mdoAML/example/zpl/matching_set1.zpl”};

param x4:=;

x1, x2, x3 and x4 are determined to be parameters based on a keyword param, the parameters x1 and x3 are determined to be assigned parameters, and the parameters x2 and x4are determined to be unassigned parameters according to the content written in the parameter value setting positions, wherein “&” represents the set character. It is assumed that a row of the code corresponding to x4 is the last row of target segment of the code, in the process of traversing any row of the code, for example, when x2 is found to be an unassigned parameter, that x2 is recorded as an unassigned parameter (for example, x2 is marked with the set character). After traversing the last row of the code, which parameters in the target segment of the code are unassigned may be obtained based on the record result. As shown in FIG. 4, an input prompt interface may be then popped up in the interface. An input prompt box corresponding to each unassigned parameter may be sequentially displayed in the input prompt interface. In order to facilitate the user to understand the meaning of each parameter, the description information of the corresponding parameter, such as the parameter name and the parameter meaning, can be displayed in association with the input prompt box corresponding to each unassigned parameter.

In some embodiments, the user inputs the parameter values corresponding to the unassigned parameters based on related prompt information. As shown in FIG. 4, it is assumed that the parameter value inputted by the user for the parameter x2 is 3, the parameter value inputted for the parameter x4 is {read “users/mdoAML/example/zpl/matching_set3.zpl”}. Based on the input operation of the user, the parameter values corresponding to the unassigned parameters inputted by the user and the unassigned parameters are correspondingly stored in a target storage space, such as a cache.

It is appreciated that the parameter values inputted by the user are not directly assigned to the unassigned parameter in the model file. That is, the parameter value setting positions of the unassigned parameters in the model file is still in the default state or a state of filling in a placeholder character, and the assignment operation does not change the model file. In addition, the purpose of executing the target segment of the code for the first time is to find whether there are unassigned parameters in the target segment of the code or not, so that the operation of loading the corresponding parameter values from the data file may not be executed for the assigned parameters giving the corresponding parameter value reading paths in the data file.

It is appreciated that, just because the state of the unassigned parameters in the model file is not changed, when the user selects a segment of the code including the unassigned parameters again for debugging operation, different parameter values may be inputted again according to actual requirements, and it is limited by other parameter values inputted for the unassigned parameters before, so great flexibility is provided for repeated debugging of the code.

In some embodiments, the prompt information corresponding to the unassigned parameters is displayed on the interface, so that the user may display the assigned parameters and the parameter values thereof while inputting the parameter values based on the prompt information, and the user may check global parameters and parameter values corresponding to the global parameters.

In some embodiments, all parameters in the target segment of the code may be identified based on the keyword adopted for defining the parameter. The prompt information corresponding to all the parameters can be displayed, that is, which parameters are in the target segment of the code can be prompted to the user. When the parameters are determined to be the assigned parameters, the parameter values corresponding to the assigned parameters may be displayed. Thus, the user may determine the unassigned parameters through an exclusive method.

After the user inputs the corresponding parameter values based on the prompt information corresponding to the unassigned parameters, in step 203, specifically, in the process of executing the target segment of the code for the second time, the model instance corresponding to the target segment of the code is generated according to the parameter values corresponding to the unassigned parameters inputted by the user and parameter values corresponding to assigned parameters in the target segment of the code.

Specifically, as described above, the assigned parameters include parameters having values that are directly given and parameters for which corresponding parameter value reading paths in the data file are given; and then the process of generating a model instance corresponding to the target segment of the code includes:

in response to the confirmation of completion of an assignment operation of the unassigned parameters triggered by the user, in a process of executing the target segment of the code for the second time:

for the unassigned parameters, loading the parameter values corresponding to the unassigned parameters from the target storage space;

for the parameters for which corresponding parameter value reading paths in the data file are given, loading the corresponding parameter values from the data file according to the parameter value reading paths; and

according to the loaded parameter values corresponding to the unassigned parameters and parameter values corresponding to the assigned parameters, generating a model instance corresponding to the target segment of the code.

As shown in FIG. 4, a “confirm” button 401 is arranged in the input prompt interface. When the user inputs the parameter values corresponding to the unassigned parameters and clicks “confirm” button 401, it is determined that the user confirms that the assignment operation of the unassigned parameters is completed, and the second execution process of the target segment of the code is triggered. In the second execution process, all the parameters are completely traversed row by row, and parameter values corresponding to all the parameters are loaded. The parameter values which are inputted by the user and correspond to the unassigned parameters are stored in the target storage space, so that the parameter values of the unassigned parameters may be loaded from the target storage space. The assigned parameters of the parameter values are not directly given, and the parameter values are loaded from the data file.

Finally, based on the parameter values of the loaded parameters and function relations such as variables and parameters described in the model file, the creation of the model instance corresponding to the target segment of the code is completed.

In order to understand the model instance, the following examples are illustrated. Assuming that a designed mathematical model includes the following inequation constraint: ax+by<10, x and y represent variables, and a, b and 10 represent parameters; the model file may include a corresponding code describing the inequation, and the code may include definitions about the variables and the parameters. It is assumed that the two parameters a and b are set as unassigned parameters, the parameter values inputted by the user based on the prompt information are parameter value reading paths respectively; and assuming that the corresponding parameter value reading paths include three parameter values: a1, a2 and a3, and b1, b2 and b3. Three specific inequation instances will be generated based on the loading result of the parameter value: a1x+b1y<10, a2x+b2y<10, a3x+b3y<10. The meaning of the corresponding instance is explained only by taking one inequation constraint as an example. The target segment of the code may include various functional relations such as equations and inequations defined in the mathematical model; each functional relation may generate one or more specific instances; and all the instances form a model instance corresponding to the target segment of the code.

In some embodiments of the present disclosure, a solver corresponding to the model instance may be called to solve variables of the model instance. The solving result of the model instance may be displayed in the interface, so that the user may check the solving result. If the solving result does not accord with the expectation, for example, the solving result does not accord with the actual operation condition of the target application system, or the running of the target application system is not suitable for being controlled according to the solving result, the user may update the previously designed mathematical model.

For example, if the previously designed mathematical model includes 15 constraint conditions and one objective function, and when the user selects 14 constraint conditions and code corresponding to the objective function as the target segment of the code to carry out running in the advanced running mode and finds that the solving result of the corresponding model instance is better than the solving result corresponding to the model instance established based on all 15 constraint conditions, the user may update the mathematical model as only including the 14 constraint conditions.

Besides, in the process of executing the target segment of the code for the second time, in order to prevent abnormal execution, grammar detection may be carried out on the target segment of the code firstly to detect whether grammar errors exist in the target segment of the code or not; and if the grammar errors exist, error reporting is carried out, so that the user corrects the grammar errors.

In conclusion, based on the advanced running mode of the model file according to some embodiments of the present disclosure, when the selected target segment of the code to be executed in the model file is analyzed, and if unassigned parameters are met, the unassigned parameters are represented in a placeholder form, and after the whole selected code is analyzed for the first time, a dialog box will be popped up for a user to set the parameter values of the unassigned parameters, so that the modeling process is executed based on the parameter values inputted by the user. The advanced running mode provides greater flexibility for the user to repeatedly debug the mathematical model for multiple times.

Moreover, based on the advanced running mode, the security of the model file may be ensured when a plurality of persons use the same mathematical model. For example, the model file is developed by the user A, while other users except the user A may be allowed to debug the model file. If only the user A has the permission to modify the model file, based on the plurality of unassigned parameters set by the user A in the model file and the advanced running mode, users other than user A may select the target segment of the code as required and assign the unassigned parameters in the target segment of the code as required in the debugging process of the model, but the other users do not have the permission to modify the model file. As such, the parameter value setting of each parameter (including the unassigned parameters) in the model file cannot be changed by the debugging processes of different users, and the security of the model file is ensured.

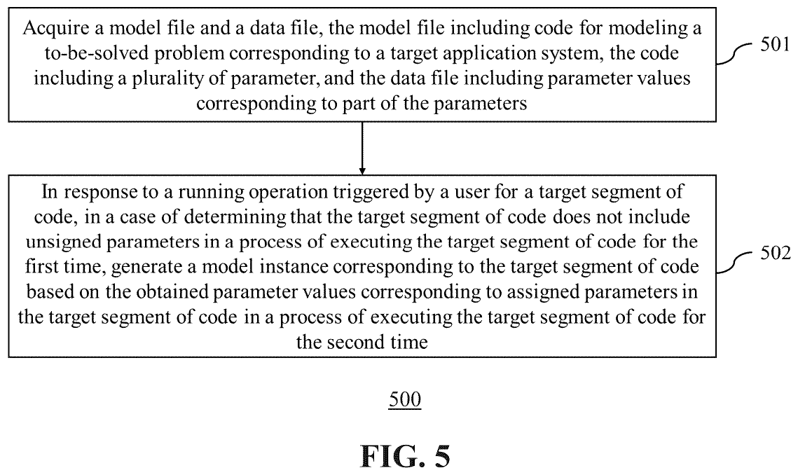

Some of the above embodiments show that there are unassigned parameters in the target segment of the code selected by the user, and the debugging process without unassigned parameters in the target segment of the code is described in combination with FIG. 5.

FIG. 5 is a flowchart of another exemplary data modeling method 500 according to some embodiments of the present disclosure. As shown in FIG. 5, method 500 may include the following steps 501 and 502, which can be implemented by a data modeling apparatus. The data modeling apparatus, which is described below, may include processing resources, storage resources, and communication interfaces.

In step 501, the data modeling apparatus may acquire a model file and a data file, the model file including code for modeling a to-be-solved problem corresponding to a target application system, the code including a plurality of parameters, and the data file at least including parameter values corresponding to part of the parameters.

In step 502, the data modeling apparatus may, in response to the running operation triggered by the user for the target segment of the code and in a case of determining that the target segment of the code does not include unassigned parameters in the process of executing the target segment of the code for the first time, generate the model instance corresponding to the target segment of the code based on the obtained parameter values corresponding to the assigned parameters in the target segment of the code in a process of executing the target segment of the code for the second time.

Therefore, when the user selects the target segment of the code and triggers a specific advanced running mode, the target segment of the code is analyzed row by row in the process of executing the target segment of the code for the first time to determine whether the unassigned parameter is in the target segment of the code or not; and if it is not found that the unassigned parameter is in the target segment of the code after the target segment of the code is traversed, the process of executing the target segment of the code for the second time is automatically executed. At the moment, it is indicated that all the parameters contained in the target segment of the code are assigned parameters. In the process of executing the target segment of the code for the second time, the model instance corresponding to the target segment of the code is generated based on the parameter values corresponding to the assigned parameters in the obtained target segment of the code. Then a related solver is called to solve the model instance.

The data modeling method according to some embodiments of the present disclosure may be applied to any application system with corresponding mathematical model modeling requirements, such as an electric power system.

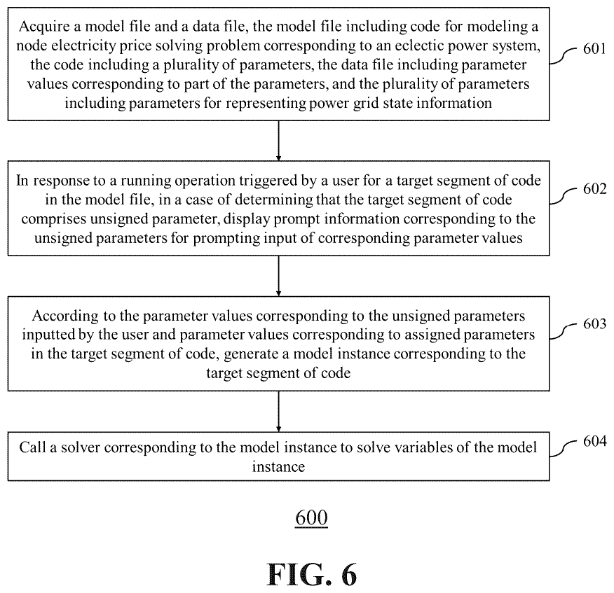

FIG. 6 is a flowchart of another exemplary data modeling method 600 of an electric power system, according to some embodiments of the present disclosure. As shown in FIG. 6, method 600 may include the following steps 601 to 604, which can be implemented by a data modeling apparatus. The data modeling apparatus, which is described below, may include processing resources, storage resources, and communication interfaces.

In step 601, the data modeling apparatus may acquire a model file and a data file, the model file including code for modeling a node electricity price solving problem corresponding to the electric power system, the code including a plurality of parameters, the data file at least including parameter values corresponding to part of the parameters, and the plurality of parameters including parameters for representing power grid state information.

In step 602, the data modeling apparatus may, in response to a running operation triggered by a user for a target segment of the code in the model file and in a case of determining that the target segment of the code include unassigned parameters, display prompt information corresponding to the unassigned parameters for prompting input of corresponding parameter values.

In step 603, the data modeling apparatus may, according to the parameter values corresponding to the unassigned parameters inputted by the user and parameter values corresponding to assigned parameters in the target segment of the code, generate a model instance corresponding to the target segment of the code.

In step 604, the data modeling apparatus may call a solver corresponding to the model instance to solve variables of the model instance.

In the electric power system, a main problem to be solved is the problem of determining node electricity price. The node electricity price refers to the marginal cost when the unit load demand is increased at a certain node under a condition that the operation characteristics and constraint conditions of various devices and resources are met, namely, the increased cost required for consuming “more than one kilowatt hour” at a certain time and a certain place is represented. Generally, “device and resources” influencing the node electricity price mainly refer to a generator set and a power transmission line, and the “running characteristics and constraint conditions” include power load balance, maximum and minimum output and climbing of the generator set, transmission capacity of the power transmission line and a power transmission section in normal and fault states and the like.

When calculating the node electricity price, a node electricity price clearing model needs to be used, which is a mathematical model used for calculating the node electricity price, and may be a model which takes variables such as active power of a unit node as decision variables, has network security constraints and takes minimization of the total cost as a target. The node electricity price clearing model is actually a linear programming model. Linear programming model is a mathematical model; the decision variables of the mathematical model are all continuous real variables; and an objective function and constraint conditions are both linear. After a standard algorithm or a solving program is used for solving, the decision variables will be divided into a basic variable and a non-basic variable, and a shadow price will be assigned to each constraint condition.

The shadow price of each constraint corresponding to each node is added to finally form the node electricity price of the nodes.

As described above, in order to calculate the node electricity price, a mathematical model is to be defined, namely the node electricity price clearing model, and then, a corresponding model file is developed by the user for the definition of the mathematical model; the model file includes a plurality of decision variables and a plurality of parameters; and the relationship and values between the parameters and the variables are described according to the objective function and various constraints defined in the mathematical model.

In addition, because the node electricity price is scheduled in real time, real-time state information of the power grid needs to be acquired for each scheduling time to form the data file, and the power grid state information corresponds to a plurality of parameters defined in the model file. The parameters representing the power grid state information include, for example, some types of data such as: related data of each unit node in the power grid system, load data of the load node, and topological structure data of the power grid system. The related data of each unit node may include: the maximum climbing rate, the maximum and minimum power generation capacity, the startup cost, the operation cost and the like of each unit node. The topological structure data of the power grid system includes the active power flow limit of each power transmission line, the connection relationship between each node and the line and the like.

As described above, when the user defines parameters in the model file, parameter values of some parameters may be assigned or not assigned. For example, parameters corresponding to dynamically changing information in some power grid state information may be set as unassigned parameters, and parameters corresponding to some stable and unchanged information may be set as assigned parameters.

When the user performs model debugging, the whole model file or one segment of the code in the model file may be selected as the debugging object (called the target segment of the code), and then the advanced running mode is selected to trigger operation of the target segment of the code. Then, as described above, firstly, whether the target segment of the code includes unassigned parameters or not is determined, and if yes, the prompt information corresponding to the unassigned parameters will be displayed. Specifically, in the process of executing the target segment of the code for the first time, whether any row of the code include the unassigned parameters or not is determined row by row, if it is determined that the unassigned parameters are included, the set character is marked for the unassigned parameters; and if execution of the target segment of the code is completed, all unassigned parameters in the target segment of the code are acquired according to the mark, and the prompt information corresponding to all the unassigned parameters is displayed. The user performs assignment operation on the unassigned parameters based on the prompt information, for example, the parameter values corresponding to certain unassigned parameters are given, or the parameter value reading paths corresponding to the unassigned parameters are given, so that the parameter values are loaded from the corresponding data file according to the reading paths subsequently.

Then, in response to the confirmation of completion of the assignment operation of the unassigned parameters triggered by the user, the unassigned parameters and the parameter values corresponding to the unassigned parameters are stored in a target storage space; and in the process of executing the target segment of the code for the second time, it includes: for the unassigned parameters, loading the parameter values corresponding to the unassigned parameters from the target storage space; for the parameters for which corresponding parameter value reading paths in the data file are given, loading the corresponding parameter values from the data file according to the parameter value reading paths; and according to the loaded parameter values corresponding to the unassigned parameters and parameter values corresponding to the assigned parameters, generating a model instance corresponding to the target segment of the code. Then, the corresponding solver is called to complete the solution of the model instance.

The content which is not detailed in some embodiments may refer to related description in other embodiments and is not detailed here.

A data modeling apparatus according to one or more embodiments of the present disclosure is described in detail below. It is appreciated that these devices can be constructed using commercially available hardware components and configured through the steps taught in this solution.

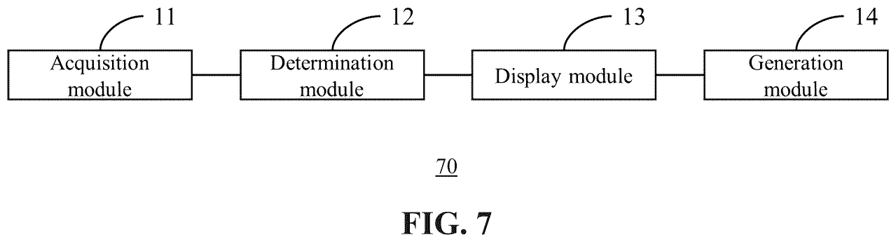

FIG. 7 is a schematic structural diagram of an exemplary data modeling apparatus 70 according to some embodiments of the present disclosure. As shown in FIG. 7, apparatus 70 may include an acquisition module 11, a determination module 12, a display module 13 and a generation module 14.

Acquisition module 11 can be configured to acquire a model file and a data file, the model file including code for modeling a to-be-solved problem corresponding to a target application system, the code including a plurality of parameters, and the data file at least including parameter values corresponding to part of the parameters.

Determination module 12 can be configured to, in response to a running operation triggered by a user for a target segment of the code in the model file, determine whether the target segment of the code includes unassigned parameters.

Display module 13 can be configured to, in a case of determining that the target segment of the code includes unassigned parameters by determination module 12, display prompt information corresponding to the unassigned parameters for prompting input of corresponding parameter values.

Generation module 14 can be configured to, according to the parameter values corresponding to the unassigned parameters inputted by the user and parameter values corresponding to assigned parameters in the target segment of the code, generate a model instance corresponding to the target segment of the code.

In some embodiments, apparatus 70 further includes a solving module (not shown) that is configured to call a solver corresponding to the model instance to solve variables of the model instance.

In some embodiments, determination module 12 can be configured to, in the process of executing the target segment of the code for the first time, determine whether any row of the code includes unassigned parameters row by row; in a case of determining that unassigned parameters are included, mark a set character for the unassigned parameters; and display module 13 can be configured to display prompt information corresponding to all the unassigned parameters.

In some embodiments, the assigned parameters include parameters having values that are directly given and parameters for which corresponding parameter value reading paths in the data file are given; and determination module 12 is specifically configured to: in the process of executing the target segment of the code for the first time, not execute an operation of loading the corresponding parameter values according to the parameter value reading paths.

In some embodiments, apparatus 70 further includes a storage module (not shown) which is configured to store the unassigned parameters and the parameter values corresponding to the unassigned parameters in a target storage space.

In some embodiments, the assigned parameters include parameters having values that are directly given and parameters for which corresponding parameter value reading paths in the data file are given; and generation module 14 is specifically configured to: in response to the confirmation of completion of the assignment operation of the unassigned parameters triggered by the user, in a process of executing the target segment of the code for the second time: for the unassigned parameters, load the parameter values corresponding to the unassigned parameters from the target storage space; for the parameters for which corresponding parameter value reading paths in the data file are given, load the corresponding parameter values from the data file according to the parameter value reading paths; and according to the loaded parameter values corresponding to the unassigned parameters and parameter values corresponding to the assigned parameters, generate a model instance corresponding to the target segment of the code.

In some embodiments, generation module 14 is further configured to perform grammar detection on the target segment of the code before generating the model instance corresponding to the target segment of the code.

In some embodiments, determination module 12 is further configured to, in response to the running operation triggered by the user for the target segment of the code and in a case of determining that the target segment of the code does not include unassigned parameters in the process of executing the target segment of the code for the first time, trigger generation module 14 to generate the model instance corresponding to the target segment of the code based on the obtained parameter values corresponding to the assigned parameters in the target segment of the code in a process of executing the target segment of the code for the second time.

Apparatus 70 shown in FIG. 7 may execute the steps provided in at least some of the abovementioned embodiments, and the detailed execution process and technical effect take part in the description in some of the abovementioned embodiments and are not repeated here.

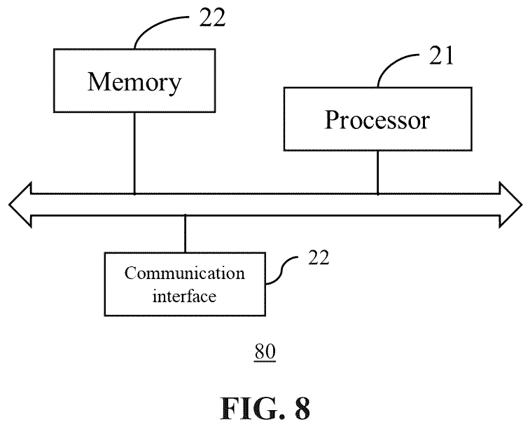

In a possible design, the structure of the data modeling apparatus shown in FIG. 7 may be realized as an electronic device. FIG. 8 is a schematic structural diagram of an exemplary electronic device 80 according to some embodiments of the present disclosure. As shown in FIG. 8, electronic device 80 may include a processor 21 (e.g., a central processing unit (CPU), a graphics processing unit (GPU), an infrastructure processing unit (IPU), a neural processing unit (NPU), an application specific integrated circuit (ASIC), or any combination thereof), a memory 22 and a communication interface 23. Executable code can be stored on memory 22. When processor 21 executes the executable code, processor 21 may at least realize the data modeling method provided in some of the abovementioned embodiments.

In addition, some embodiments of the present disclosure provide a non-temporary machine-readable storage medium; executable code is stored on the non-temporary machine-readable storage medium; and when processor 21 of electronic device 80 executes the executable code, processor 21 may at least realize the data modeling method provided in some of the abovementioned embodiments.

The apparatus described above are only schematic, and the network elements described therein as a description of the detached parts may or may not be physically separated. Some or all of the modules can be selected according to actual needs to realize the purpose of some embodiments.

It is appreciated that the various embodiments may be implemented by means of software plus a necessary general hardware platform, and definitely may also be implemented by a combination of hardware and software. Based on this understanding, the abovementioned technical solution may be embodied in the form of a computer product in essence or a part that contributes to the prior art, and the present disclosure may take the form of a computer program product implemented on one or more computer-available storage media (including but not limited to disk memory, CD-ROM, optical memory, etc.) containing computer-available program code.

Finally, it is be noted that the above embodiments are only used for illustrating the technical solutions of the present disclosure, not for limiting them, and although the present disclosure is described in detail with reference to the foregoing embodiments, it is appreciated that it can still modify the technical solutions recorded in the abovementioned embodiments, or replace some of the technical features therein, and these modifications or substitutions do not make the essence of the corresponding technical solutions detached from the spirit and scope of the technical solutions of the embodiments of the present disclosure.

The embodiments may further be described using the following clauses:
1. A data modeling method, including:
acquiring a model file and a data file, the model file including code for modeling a to-be-solved problem corresponding to a target application system, the code including a plurality of parameters, and the data file including parameter values corresponding to part of the parameters;
in response to a running operation triggered for a target segment of the code in the model file and a determination that the target segment of the code including unassigned parameters, displaying prompt information corresponding to the unassigned parameters for prompting input of parameter values corresponding to the unassigned parameters; and
generating a model instance corresponding to the target segment of the code according to the parameter values corresponding to the unassigned parameters inputted and parameter values corresponding to assigned parameters in the target segment of the code.
2. The method according to clause 1, further including:
calling a solver corresponding to the model instance to solve variables of the model instance.
3. The method according to clause 1 or 2, wherein displaying the prompt information corresponding to the unassigned parameters includes:
in a process of executing the target segment of the code for the first time, determining whether a row of the code includes the unassigned parameters in a row by row manner;
in response to a determining that the unassigned parameters are included in the row, marking the unassigned parameters with a set character;
in a response to a determination that the target segment of the code is completely executed, acquiring all the unassigned parameters included in the target segment of the code according to the marking character; and
displaying the prompt information corresponding to all the unassigned parameters.
4. The method according to clause 3, wherein the assigned parameters include parameters having values that are directly given or parameters for which corresponding parameter value reading paths in the data file are given; and
in the process of executing the target segment of the code for the first time, an operation of loading the corresponding parameter values according to the parameter value reading paths is not executed.
5. The method according to clause 3, further including:
displaying prompt information corresponding to the assigned parameters.
6. The method according to any of clauses 1 to 5, further including:
storing the unassigned parameters and the parameter values corresponding to the unassigned parameters in a target storage space.
7. The method according to clause 6, wherein the assigned parameters include parameters having values that are directly given or parameters for which corresponding parameter value reading paths in the data file are given; and
generating the model instance corresponding to the target segment of the code includes:
in response to a confirmation of completion of an assignment operation of the unassigned parameters triggered, in a process of executing the target segment of the code for the second time:
   for the unassigned parameters, loading the parameter values corresponding to the unassigned parameters from the target storage space;
   for the parameters for which corresponding parameter value reading paths in the data file are given, loading the corresponding parameter values from the data file according to the parameter value reading paths; and
   generating the model instance corresponding to the target segment of the code according to the loaded parameter values corresponding to the unassigned parameters and parameter values corresponding to the assigned parameters.
8. The method according to any of clauses 1 to 7, further including:
in response to the running operation triggered for the target segment of the code and a determination that the target segment of the code not including the unassigned parameters in a process of executing the target segment of the code for the first time, generating the model instance corresponding to the target segment of the code based on an obtained parameter values corresponding to the assigned parameters in the target segment of the code in a process of executing the target segment of the code for the second time.
9. A data modeling apparatus, including:
a memory; and
one or more processors communicatively coupled with the memory, the memory storing a set of instructions that are executable by one or more processors of the data modeling apparatus to cause the data modeling apparatus to perform operations, including:
   acquiring a model file and a data file, the model file including code for modeling a to-be-solved problem corresponding to a target application system, the code including a plurality of parameters, and the data file including parameter values corresponding to part of the parameters;
   in response to a running operation triggered for a target segment of the code in the model file and a determination that the target segment of the code including unassigned parameters, providing prompt information corresponding to the unassigned parameters for display, for prompting input of parameter values corresponding to the unassigned parameters; and
   generating a model instance corresponding to the target segment of the code according to the parameter values corresponding to the unassigned parameters inputted and parameter values corresponding to assigned parameters in the target segment of the code.
10. The apparatus according to clause 9, wherein the operations further include: calling a solver corresponding to the model instance to solve variables of the model instance.
11. The apparatus according to clause 9 or 10, wherein providing prompt information corresponding to the unassigned parameters for display:
in a process of executing the target segment of the code for the first time, determining whether a row of the code includes the unassigned parameters in a row by row manner;
in response to a determining that the unassigned parameters are included in the row, marking the unassigned parameters with a set character;
in a response to a determination that the target segment of the code is completely executed, acquiring all the unassigned parameters included in the target segment of the code according to the marking character; and
triggering to display the prompt information corresponding to all the unassigned parameters.
12. The apparatus according to clause 11, wherein the assigned parameters include parameters having values that are directly given or parameters for which corresponding parameter value reading paths in the data file are given; and
in the process of executing the target segment of the code for the first time, an operation of loading the corresponding parameter values according to the parameter value reading paths is not executed.
13. The apparatus according to clause 12, wherein the operations further include:
displaying prompt information corresponding to the assigned parameters.
14. The apparatus according to any of clauses 9 to 13, wherein the operations further include:
storing the unassigned parameters and the parameter values corresponding to the unassigned parameters in a target storage space.
15. The apparatus according to clause 14, wherein the assigned parameters include parameters having values that are directly given or parameters for which corresponding parameter value reading paths in the data file are given; and
wherein generating the model instance corresponding to the target segment of the code includes:
in response to a confirmation of completion of an assignment operation of the unassigned parameters triggered, in a process of executing the target segment of the code for the second time:
   for the unassigned parameters, load the parameter values corresponding to the unassigned parameters from the target storage space;
   for the parameters for which corresponding parameter value reading paths in the data file are given, load the corresponding parameter values from the data file according to the parameter value reading paths; and
   generate the model instance corresponding to the target segment of the code according to the loaded parameter values corresponding to the unassigned parameters and parameter values corresponding to the assigned parameters.
16. The apparatus according to any of clauses 9 to 15, wherein the operations further include:
in response to the running operation triggered for the target segment of the code and a determination that the target segment of the code not including the unassigned parameters in a process of executing the target segment of the code for the first time, generating the model instance corresponding to the target segment of the code based on an obtained parameter values corresponding to the assigned parameters in the target segment of the code in a process of executing the target segment of the code for the second time.
17. A non-transitory computer-readable storage medium, storing a set of instructions that are executable by one or more processors of a device to cause the device to perform operations for data modeling, the operations including:
acquiring a model file and a data file, the model file including code for modeling a to-be-solved problem corresponding to a target application system, the code including a plurality of parameters, and the data file including parameter values corresponding to part of the parameters;
in response to a running operation triggered for a target segment of the code in the model file and a determination that the target segment of the code including unassigned parameters, displaying prompt information corresponding to the unassigned parameters for prompting input of parameter values corresponding to the unassigned parameters; and
generating a model instance corresponding to the target segment of the code according to the parameter values corresponding to the unassigned parameters inputted and parameter values corresponding to assigned parameters in the target segment of the code.
18. The non-transitory computer-readable storage medium according to clause 17, wherein the operations further include:
calling a solver corresponding to the model instance to solve variables of the model instance.
19. The non-transitory computer-readable storage medium according to clause 17 or 18, wherein displaying the prompt information corresponding to the unassigned parameters includes:
in a process of executing the target segment of the code for the first time, determining whether a row of the code includes the unassigned parameters in a row by row manner;
in response to a determining that the unassigned parameters are included, marking the unassigned parameters with a set character;
in a response to a determination that the target segment of the code is completely executed, acquiring all the unassigned parameters included in the target segment of the code according to the marking character; and
displaying the prompt information corresponding to all the unassigned parameters.
20. The non-transitory computer-readable storage medium according to clause 19, wherein the assigned parameters include parameters having values are directly given or parameters for which corresponding parameter value reading paths in the data file are given; and
in the process of executing the target segment of the code for the first time, an operation of loading the corresponding parameter values according to the parameter value reading paths is not executed.
21. The non-transitory computer-readable storage medium according to clause 19, wherein the operations further include:
displaying prompt information corresponding to the assigned parameters.
22. The non-transitory computer-readable storage medium according to any of clauses 17 to 21, wherein the operations further include:
storing the unassigned parameters and the parameter values corresponding to the unassigned parameters in a target storage space.
23. The non-transitory computer-readable storage medium according to clause 22, wherein the assigned parameters include parameters having values that are directly given or parameters for which corresponding parameter value reading paths in the data file are given; and
generating the model instance corresponding to the target segment of the code includes:
in response to a confirmation of completion of an assignment operation of the unassigned parameters triggered, in a process of executing the target segment of the code for the second time:
   for the unassigned parameters, loading the parameter values corresponding to the unassigned parameters from the target storage space;
   for the parameters for which corresponding parameter value reading paths in the data file are given, loading the corresponding parameter values from the data file according to the parameter value reading paths; and
   generating the model instance corresponding to the target segment of the code according to the loaded parameter values corresponding to the unassigned parameters and parameter values corresponding to the assigned parameters.
24. The non-transitory computer-readable storage medium according to any of clauses 17 to 23, wherein the operations further include:
in response to the running operation triggered for the target segment of the code and a determination that the target segment of the code not including the unassigned parameters in a process of executing the target segment of the code for the first time, generating the model instance corresponding to the target segment of the code based on an obtained parameter values corresponding to the assigned parameters in the target segment of the code in a process of executing the target segment of the code for the second time.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the disclosure disclosed herein. It is intended that the specification and examples be considered as exemplary only, with a true scope and spirit of the disclosure being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

It should be understood that the disclosed technical content may be implemented in other ways. The apparatus embodiments described above are only schematic. For example, the division of the units is only a logical function division. In actual implementations, there may be another division manner. For example, multiple units or components may be combined or integrated into another system, or some features can be ignored or not implemented. In addition, the displayed or discussed mutual coupling or direct coupling or communication connection may be indirect coupling or communication connection through some interfaces, units, or modules, which may be in electrical or other forms.

The units described as separate components may or may not be physically separated, and the components displayed as units may or may not be physical units, that is, they may be located in one place or may be distributed to a plurality of network units. Part of or all the units may be selected according to actual needs to achieve the purpose of the solution of the present embodiment.

In addition, the functional units in various embodiments of the present disclosure may be integrated into one processing unit, or each unit may exist alone physically, or two or more units may be integrated into one unit. The integrated units described above may be implemented either in the form of hardware or in the form of a software functional unit.

If the integrated units are implemented in the form of a software functional unit and sold or used as an independent product, they may be stored in a quantum computer-readable storage medium. Based on such an understanding, the technical solutions of the present disclosure essentially, or the part making contributions to the prior art, or all or part of the technical solutions may be embodied in the form of a software product. The quantum computer software product is stored in a storage medium and includes several instructions used for causing a quantum computer device to execute all or part of steps of the methods in various embodiments of the present disclosure.

The above are only preferred implementations of the present disclosure. It should be pointed out that, for those of ordinary skill in the art, several improvements and retouches may further be made without departing from the principles of the present disclosure. These improvements and retouches should also be regarded as the scope of protection of the present specification.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A data modeling method, comprising:
acquiring a model file and a data file, the model file comprising code for modeling a to-be-solved problem corresponding to a target application system, the code comprising a plurality of parameters, and the data file comprising parameter values corresponding to part of the parameters;
in response to a running operation triggered for a target segment of the code in the model file and a determination that the target segment of the code comprising unassigned parameters, displaying prompt information corresponding to the unassigned parameters for prompting input of parameter values corresponding to the unassigned parameters; and
generating a model instance corresponding to the target segment of the code according to the parameter values corresponding to the unassigned parameters inputted and parameter values corresponding to assigned parameters in the target segment of the code.

2. The method according to claim 1, further comprising:
calling a solver corresponding to the model instance to solve variables of the model instance.

3. The method according to claim 1, wherein displaying the prompt information corresponding to the unassigned parameters comprises:
in a process of executing the target segment of the code for the first time, determining whether a row of the code comprises the unassigned parameters in a row by row manner;
in response to a determining that the unassigned parameters are comprised in the row, marking the unassigned parameters with a set character;
in a response to a determination that the target segment of the code is completely executed, acquiring all the unassigned parameters comprised in the target segment of the code according to the marking character; and
displaying the prompt information corresponding to all the unassigned parameters.

4. The method according to claim 3, wherein the assigned parameters comprise parameters having values that are directly given or parameters for which corresponding parameter value reading paths in the data file are given; and
in the process of executing the target segment of the code for the first time, an operation of loading the corresponding parameter values according to the parameter value reading paths is not executed.

5. The method according to claim 3, further comprising:
displaying prompt information corresponding to the assigned parameters.

6. The method according to claim 1, further comprising:
storing the unassigned parameters and the parameter values corresponding to the unassigned parameters in a target storage space.

7. The method according to claim 6, wherein the assigned parameters comprise parameters having values that are directly given or parameters for which corresponding parameter value reading paths in the data file are given; and
generating the model instance corresponding to the target segment of the code comprises:
in response to a confirmation of completion of an assignment operation of the unassigned parameters triggered, in a process of executing the target segment of the code for the second time:
for the unassigned parameters, loading the parameter values corresponding to the unassigned parameters from the target storage space;
for the parameters for which corresponding parameter value reading paths in the data file are given, loading the corresponding parameter values from the data file according to the parameter value reading paths; and
generating the model instance corresponding to the target segment of the code according to the loaded parameter values corresponding to the unassigned parameters and parameter values corresponding to the assigned parameters.

8. The method according to claim 1, further comprising:
in response to the running operation triggered for the target segment of the code and a determination that the target segment of the code not comprising the unassigned parameters in a process of executing the target segment of the code for the first time, generating the model instance corresponding to the target segment of the code based on an obtained parameter values corresponding to the assigned parameters in the target segment of the code in a process of executing the target segment of the code for the second time.

9. A data modeling apparatus, comprising:
a memory; and
one or more processors communicatively coupled with the memory, the memory storing a set of instructions that are executable by one or more processors of the data modeling apparatus to cause the data modeling apparatus to perform operations, comprising:
acquiring a model file and a data file, the model file comprising code for modeling a to-be-solved problem corresponding to a target application system, the code comprising a plurality of parameters, and the data file comprising parameter values corresponding to part of the parameters;
in response to a running operation triggered for a target segment of the code in the model file and a determination that the target segment of the code comprising unassigned parameters, providing prompt information corresponding to the unassigned parameters for display, for prompting input of parameter values corresponding to the unassigned parameters; and
generating a model instance corresponding to the target segment of the code according to the parameter values corresponding to the unassigned parameters inputted and parameter values corresponding to assigned parameters in the target segment of the code.

10. The apparatus according to claim 9, wherein the operations further comprise:
calling a solver corresponding to the model instance to solve variables of the model instance.

11. The apparatus according to claim 9, wherein providing prompt information corresponding to the unassigned parameters for display:
in a process of executing the target segment of the code for the first time, determining whether a row of the code comprises the unassigned parameters in a row by row manner;
in response to a determining that the unassigned parameters are comprised in the row, marking the unassigned parameters with a set character;
in a response to a determination that the target segment of the code is completely executed, acquiring all the unassigned parameters comprised in the target segment of the code according to the marking character; and
triggering to display the prompt information corresponding to all the unassigned parameters.

12. The apparatus according to claim 11, wherein the assigned parameters comprise parameters having values that are directly given or parameters for which corresponding parameter value reading paths in the data file are given; and
in the process of executing the target segment of the code for the first time, an operation of loading the corresponding parameter values according to the parameter value reading paths is not executed.

13. The apparatus according to claim 12, wherein the operations further comprise:
displaying prompt information corresponding to the assigned parameters.

14. The apparatus according to claim 9, wherein the operations further comprise:
storing the unassigned parameters and the parameter values corresponding to the unassigned parameters in a target storage space.

15. The apparatus according to claim 14, wherein the assigned parameters comprise parameters having values that are directly given or parameters for which corresponding parameter value reading paths in the data file are given; and
wherein generating the model instance corresponding to the target segment of the code comprises:
in response to a confirmation of completion of an assignment operation of the unassigned parameters triggered, in a process of executing the target segment of the code for the second time:
for the unassigned parameters, load the parameter values corresponding to the unassigned parameters from the target storage space;
for the parameters for which corresponding parameter value reading paths in the data file are given, load the corresponding parameter values from the data file according to the parameter value reading paths; and
generate the model instance corresponding to the target segment of the code according to the loaded parameter values corresponding to the unassigned parameters and parameter values corresponding to the assigned parameters.

16. The apparatus according to claim 9, wherein the operations further comprise:
in response to the running operation triggered for the target segment of the code and a determination that the target segment of the code not comprising the unassigned parameters in a process of executing the target segment of the code for the first time, generating the model instance corresponding to the target segment of the code based on an obtained parameter values corresponding to the assigned parameters in the target segment of the code in a process of executing the target segment of the code for the second time.

17. A non-transitory computer-readable storage medium, storing a set of instructions that are executable by one or more processors of a device to cause the device to perform operations for data modeling, the operations comprising:
acquiring a model file and a data file, the model file comprising code for modeling a to-be-solved problem corresponding to a target application system, the code comprising a plurality of parameters, and the data file comprising parameter values corresponding to part of the parameters;
in response to a running operation triggered for a target segment of the code in the model file and a determination that the target segment of the code comprising unassigned parameters, displaying prompt information corresponding to the unassigned parameters for prompting input of parameter values corresponding to the unassigned parameters; and
generating a model instance corresponding to the target segment of the code according to the parameter values corresponding to the unassigned parameters inputted and parameter values corresponding to assigned parameters in the target segment of the code.

18. The non-transitory computer-readable storage medium according to claim 17, wherein the operations further comprise:
calling a solver corresponding to the model instance to solve variables of the model instance.

19. The non-transitory computer-readable storage medium according to claim 17, wherein displaying the prompt information corresponding to the unassigned parameters comprises:
in a process of executing the target segment of the code for the first time, determining whether a row of the code comprises the unassigned parameters in a row by row manner;
in response to a determining that the unassigned parameters are comprised, marking the unassigned parameters with a set character;
in a response to a determination that the target segment of the code is completely executed, acquiring all the unassigned parameters comprised in the target segment of the code according to the marking character; and
displaying the prompt information corresponding to all the unassigned parameters.

20. The non-transitory computer-readable storage medium according to claim 19, wherein the assigned parameters comprise parameters having values are directly given or parameters for which corresponding parameter value reading paths in the data file are given; and
in the process of executing the target segment of the code for the first time, an operation of loading the corresponding parameter values according to the parameter value reading paths is not executed.
